(19) United States
(12) Patent Application Publication
(10) Pub. No.: US 2024/0397631 A1
(43) Pub. Date: Nov. 28, 2024

(54) METHOD OF SEGMENTED ELECTROPLATING GOLD FINGER

(71) Applicant: Gold Circuit Electronics Ltd., Taoyuan (TW)

(72) Inventor: Chen-Tse Yang, Taoyuan (TW)

(73) Assignee: Gold Circuit Electronics Ltd., Taoyuan (TW)

(21) Appl. No.: 18/498,078

(22) Filed: Oct. 31, 2023

(30) Foreign Application Priority Data
May 22, 2023 (CN) 202310579680.6

(51) Int. Cl. H05K 3/18; H05K 3/00; H05K 3/30; H05K 3/40

(52) U.S. Cl. CPC H05K 3/188; H05K 3/0047; H05K 3/305; H05K 3/306; H05K 3/4015; H05K 2203/0121; H05K 2203/0582; H05K 2203/0723

(57) ABSTRACT

A method of a segmented electroplating golden finger includes a substrate, which is drilled and plated, and including: a. first etching, forming circuit patterns and gold finger parts on the substrate, the gold finger part is composed of several mutually independent gold fingers, a lead channel is provided between the two adjacent gold fingers, and a side lead connected to each gold finger is arranged on the lead channel; b. solder resist, solder resist protection for the etched substrate; c. the gold fingers partly covered with a wet film; d. parallel exposure to perform image transfer; e. gold finger electroplating; f. adhesive glue; g. second etching, removing the leads, completing a finished product.

### CROSS-REFERENCE TO RELATED APPLICATION

This application claims the priority benefit of China application serial no. 202310579680.6, filed on May 22, 2023. The entirety of the above-mentioned patent application is hereby incorporated by reference herein and made a part of this specification.

### BACKGROUND

### Technical Field

The disclosure relates to a method of manufacturing a printed-circuit board (PCB), and more particularly, to a method of a segmented electroplating gold finger.

### Description of Related Art

A connecting finger is a component that transmits signals on computer hardware (such as between a memory and a memory slot, a display card and a display card slot). It is composed of many golden conductive contacts, and it is called “gold finger” because of a gold-plated surface thereof and an arrangement of the conductive contacts like a finger.

A copper surface of most of the gold fingers is required to be covered with electroplating gold to ensure durability and good conductivity thereof. Electroplating is required to be conducted with each other for completion. In addition, a segmented gold finger and a graded gold finger are designed without a lead when designed by a client. It is necessary for a circuit board factory to design and add the lead to form a conduction network. After manufacture of the electroplating gold is completed, the lead will be removed. Therefore, it is the most commonly used way to connect a conductive wire between the two adjacent gold fingers to enable them to be connected, such as the “Method for Electroplating Gold on Gold Finger by Sectional Grading” (CN112911831A) disclosed in the Chinese invention patent application.

However, this kind of process method has the risk of overhang in the actual production, and the overhang of the gold finger is easy to fall off during the insertion and removal process. As shown in FIG. 1A, there is about 1.5 mil of overhang at a segment D (for example, suspended on a copper line). If it falls around the component when plugging and unplugging a device, there will be a risk of short circuit. Therefore, a new method of generating the gold finger is needed to avoid an issue of overhang in the manufacturing process of the gold finger.

### SUMMARY

An objective of the disclosure is to provide a method of a segmented electroplating gold finger, in which through improvement of a process, an issue of overhang may be effectively avoided, a yield rate of a product may be improved, and a cost may be reduced.

In order to achieve the above objective, a technical solution adopted in the disclosure is a method of a segmented electroplating gold finger, including a substrate, which is drilled and electroplated, and including:
a. first etching, forming circuit patterns and gold finger parts on the substrate, wherein the gold finger part is composed of several mutually independent gold fingers, a lead channel is provided between the two adjacent gold fingers, and a side lead connected to each of the gold fingers is arranged on the lead channel;
b. solder resist, performing solder resist protection on the etched substrate;
c. the gold fingers partly covered with a wet film;
d. parallel exposure to perform image transfer;
e. gold finger electroplating;
f. an adhesive glue to protect the gold finger and a circuit that is required to be retained;
g. second etching, removing the side lead, and completing a finished product.

In the technical solution, in the step a, each of the golden fingers is composed of several segmented parts arranged longitudinally. The segmented parts near an outside are connected to an external circuit, and the remaining segmented parts are respectively connected to the side lead through a conductive wire.

In the technical solution, one end of the side lead is connected to the gold finger, and another end is connected to a bus.

In the technical solution, between the step a and the step b, detection of a size specification of the gold finger is performed, and a length tolerance of the gold finger is controlled to be +/−0.05 mm.

In the technical solution, in the step d, a filin tablet is pasted on the substrate, placed under a parallel exposure machine for exposure, and after developing, the filin tablet is separated to expose a circuit to be etched, and the image transfer is completed.

In the technical solution, the lead channel is composed of long side intervals of the two adjacent gold fingers, and a width of the lead channel on an original manuscript is not less than 0.35 mm.

Due to the use of the technical solution, the disclosure has the following advantages compared to the conventional technology.
1. In the disclosure, the side lead is formed by arranging the lead between the two adjacent gold fingers. Compared to the lead arrangement in the past, the side lead may completely avoid the issue of overhang on a short side of each of sections of the gold fingers (an insert position), thereby improving product performance. At the same time, avoidance of the issue of overhang also improves alignment of the gold finger, that is, accuracy of a distance relationship between each of points, and improves assembly accuracy.
2. Due to the use of the side lead, the size of each of the gold fingers has been determined during the first etching, and no further damage is involved in the later process (the solder resist protection has been performed on the gold finger before the second etching). Therefore, the detection process of the gold finger is only required to be performed after the first etching. The accuracy is improved, and the tolerance range is reduced to only +/−0.05 mm. As a result, the detection process is saved once, the process is simplified, efficiency is improved, product accuracy is improved, and contact with an insertion end is better.
3. It is precisely because the segmented (sectioned) gold finger may be formed after the first etching, so the size of the gold finger may be accurately measured, and if it is found that it is not within the tolerance range, it may be reworked. Compared to the need to wait until the second etching to form the segmented form in the past (when there is a deviation in the second etching state, it is impossible or difficult to repair and form a defective product), in the disclosure, the size may be adjusted in time to reduce scrapped products and reduce the manufacturing cost.
4. The arrangement of the side lead in the disclosure is applicable to the process of various gold finger products, as long as the width of the lead channel is satisfied, and there is no need to change circuit distribution of an original design manuscript of the client, which is easy to use and widely used.

### BRIEF DESCRIPTION OF THE DRAWINGS

FIG. 1A is a schematic partial diagram of a gold finger in the conventional technology.

FIG. 1B is a block diagram of a process flow according to Embodiment 1 of the disclosure.

FIG. 2 is a schematic diagram of distribution of a gold finger after first etching in Embodiment 1 of the disclosure.

FIG. 3 is a schematic diagram of distribution of a golden finger after second etching in Embodiment 1 of the disclosure.

FIG. 4 is a diagram of multi-point dimensional tolerance measurement for a gold finger in Embodiment 1 of the disclosure.

### DETAILED DESCRIPTION OF DISCLOSED EMBODIMENTS

The disclosure will be further described below in combination with the accompanying drawings and embodiments.

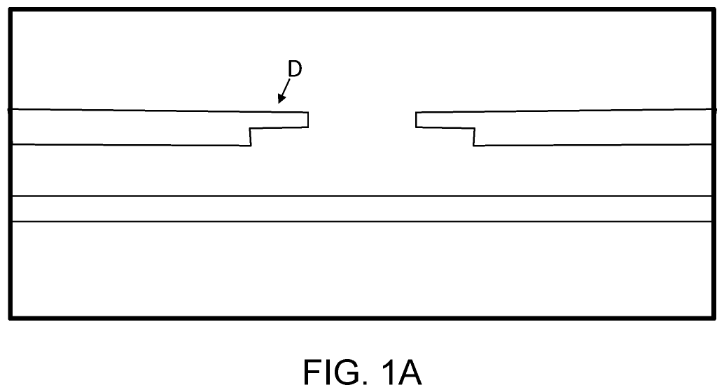

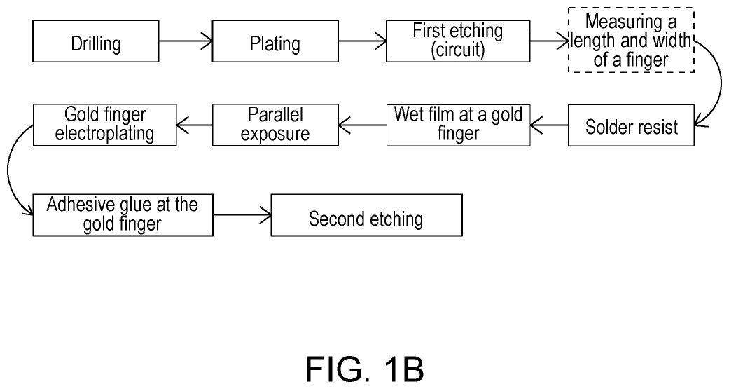

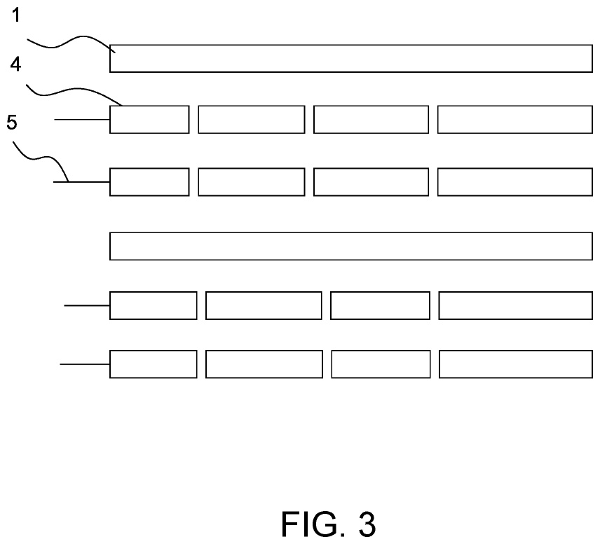

Embodiment 1: Referring to FIGS. 1B, 2, 3, and 4, a method of a segmented electroplating gold finger includes a substrate, and the substrate is drilled and plated, including:
a. Acid etching is used for first etching to form circuit patterns and segmented gold finger parts on the substrate. The gold finger part is composed of several mutually independent gold fingers 1. A lead channel 2 the two adjacent gold fingers 1 is provided between the two adjacent gold fingers 1, and a side lead 3 connected to each of the golden fingers 1 is arranged on the lead channel 2. The lead channel 2 is composed of long side intervals of the two adjacent golden fingers 1. A width W of the lead channel 2 on an original manuscript is not less than 0.35 mm. The original manuscript here refers to a layout design draft of an integrated circuit designed by a designer, and the side lead 3 may be disposed for a process of the golden finger 1 above the width;
b. Solder resist, in which solder resist protection is performed on the etched substrate; mainly after an outer circuit and the golden finger are completed, the solder resist protection is required to be performed on the circuit to prevent the outer circuit from oxidation or soldering short circuit. Solder resist ink may be generally used for the solder resist protection, and a coating thickness is usually 20 μm to 30 μm;
c. The gold finger partly covered with a wet film, which is used to prevent gold plating on a conductive wire during a process of gold plating fingers, resulting in waste of resources. The wet film is a kind of photosensitive ink. A type of the ink may adopt ink commonly used in the industry. After being applied to the conductive wire of the gold finger of a PCB board, it is cured and attached to a surface of the substrate through ultraviolet light, so as to achieve a function of blocking electroplating and etching;
d. Parallel exposure, in which in order to reduce a position deviation of the gold finger, it is necessary to use a horizontal exposure machine with higher exposure accuracy and better uniformity to perform image transfer. A specific operation is to paste a filin tablet on the substrate, place it under the parallel exposure machine for exposure, wait for the development and separate the filin tablet to expose a circuit to be etched, and complete the image transfer;
e. Gold finger electroplating, in which the gold finger is electroplated, and a layer of electroplating gold is added to the surface;
f. Adhesive glue, in which the whole board is pasted with protective glue (such as anti-electroplating blue glue), and the position is required to be etched twice to remove the corresponding protective glue;
g. Second etching, in which the lead is removed, and a finished product is completed. Alkaline (or acidic, currently unconventional) etching is used for the second etching, and an etching portion etches off the side lead of the gold finger, and finished product is shown in FIG. 3. Here, between the step a and the step b, there may also be a step of measuring a length and width of the finger. In this way, in the disclosure, the length and width of the gold finger may be measured at one time to simplify the process, instead of measuring the length and width of the gold finger at different phases (for example, in the conventional technology, the width of the gold finger is measured after the first etching, and the length of the gold finger is measured after the second etching).

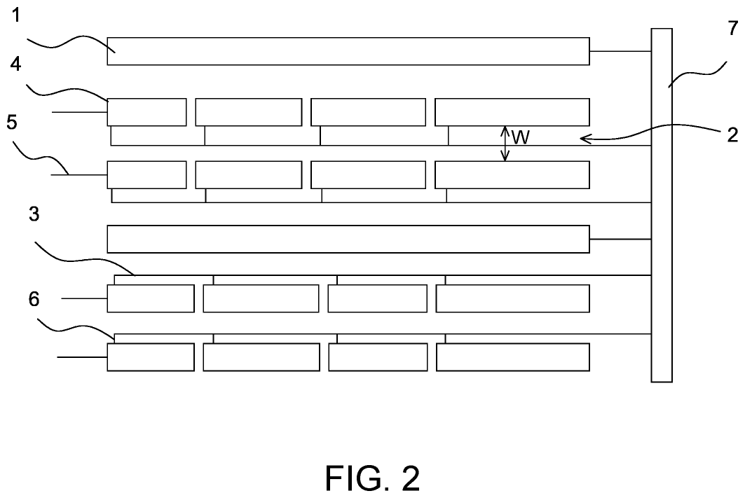

Specifically, as shown in FIG. 2, in the step a, each of the gold fingers 1 is composed of several segmented parts 4 arranged longitudinally, and the segmented parts 4 near the outside are connected to outer leads 5. The remaining segmented parts are respectively connected to the side leads 3 through conductive wires 6, and a right end of the side leads 3 is connected to a bus 7. The side lead 3 is a conductive lead of the gold finger 1 when electroplated with gold. The electroplated gold finger 1 needs the lead to be connected to an edge (the bus) of the printed circuit board to ensure that the gold finger is connected to electroplating equipment during a gold-plating process. In this embodiment, the first etching is about to form the segmented parts 4, which is different from the need to be formed in the second etching in the past (in the past, the gold finger itself (a direct lead) was used as a guide line during gold plating, and the segments may not be formed in the first etching). As a result, the benefit is that dimensional accuracy of the gold finger may be ensured, and even if there is a mistake, it may be reworked. In addition, in the past, dimensional deviation was only found after the second etching, so it may not be repaired and became a scrap product. Therefore, by adopting the method in this embodiment, defective products caused by the dimensional deviation may be greatly reduced, and a yield rate may be improved.

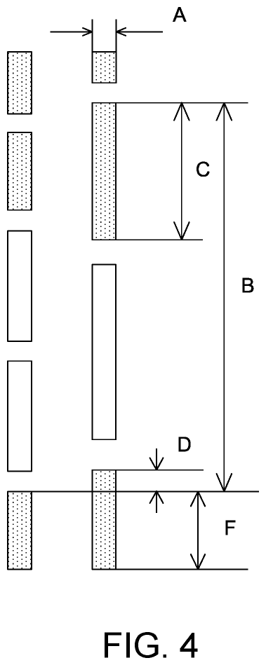

Between the step a and the step b, that is, after the first etching is completed, a size of each of parts of the segmented gold finger has been determined. At this time, a size specification of the gold finger is detected once, and a length tolerance of the gold finger may reach +/−0.05 mm. Since a method of the side lead is adopted in this embodiment, the gold finger is not affected by the second etching (the lead is on the side, and a surface of the gold finger is not damaged when the lead is removed), which reduces the loss and may ensure the dimensional accuracy thereof during the first etching. Detection data is as the following table (compare with FIG. 4). The direct lead is the conventional technology, and the side lead is a technical solution in this embodiment.

| Measure- | | | | | Direct | Side |
|---|---|---|---|---|---|---|
| ment | | | upper | lower | lead | lead |
| position | Specification | Tolerance | limit | limit | CPK | CPK |
| A | 0.45 | ±0.050 | 0.5 | 0.4 | 1.32 | 1.43 |
| B | 6.9 | ±0.050 | 6.95 | 6.85 | 0.88 | 2.79 |
| C | minimum value | 2.4 | / | 2.4 | 1.63 | 1.72 |
| D | 0.4 | ±0.050 | 0.45 | 0.35 | 7.56 | 9.71 |
| F | minimum value | 1.6 | / | 1.6 | 0.56 | 2.27 |

In the above table, the upper limit and lower limit may be obtained by the specification with the tolerance, and the “minimum value” recorded in the specification indicates that only a lower limit value is controlled (only above this value, not less than this value). The specification and the tolerance are subject to actual design requirements. In FIG. 4, there are a first row including four segments of the gold fingers and a second row including five segments of the gold fingers respectively. Measurement positions A to F are detected by using a 3D measuring instrument, which are respectively measured as A: a width of a first gold finger in the first row; B: a length from a top of a second gold finger in the first row to a top of a fifth gold finger in the second row; C: a length of the second gold finger in the first row; D: a length from a top of a fourth gold finger in the first row to the top of the fifth gold finger in the second row; F; a length of the fifth gold finger in the second row. In addition, CPK, an abbreviation of Complex Process Capabilityindex, is an index used by modern enterprises to express the process capability, is a ratio of an allowable maximum variation range of process performance to normal deviation of the process, and is also to confirm a degree to which the characteristics meet the specification, as a basis for continuous improvement of the process.

Rating standards of CPK: (according to the standards, corresponding countermeasures may be made to a calculated index of the process capability)
Class A++, CPK≥2.0, which is premium, and cost reduction may be considered;
Class A+, 2.0≥CPK≥1.67, which is excellent, and should be maintained;
Class A, 1.67>CPK≥1.33, which is good, has good capability, and has a stable state, but should try to be upgraded to Class A+;
Class B, 1.33>CPK≥1.0, which is average, the state is average, a slight variation in process factors may lead to adverse effects, and various resources and methods should be used to be upgraded to Class A;
Class C, 1.0>CPK≥0.67, which is poor, there are many defects in the process, and the capability thereof is required to be improved;
Class D, 0.67>CPK, which is unacceptable, the capability thereof is too poor, and the design process should be considered to be reorganized.

According to the above descriptions of ranges of the CPK indexes, through the implementation of the technical solution in the disclosure, the detection index of each of points has been improved to varying degrees, all reaching Class A or above, which indicates that the improvement of the method in this embodiment has achieved the objective of optimizing the process, may improve alignment capability, tolerance capability, and product performance of gold finger products, and reduce a rate of the defective products.

What is claimed is:

1. A method of a segmented electroplating gold finger, comprising a substrate, which is drilled and electroplated, wherein the method of the segmented electroplating gold finger comprises:
a. first etching, forming circuit patterns and gold finger parts on the substrate, wherein the gold finger part is composed of several mutually independent gold fingers, a lead channel is provided between the two adjacent gold fingers, and a side lead connected to each of the gold fingers is arranged on the lead channel;
b. solder resist, performing solder resist protection on the etched substrate;
c. the gold fingers partly covered with a wet film;
d. parallel exposure to perform image transfer;
e. gold finger electroplating;
f. an adhesive glue to protect the gold finger and a circuit that is required to be retained;
g. second etching, removing the side lead, and completing a finished product.

2. The method of the segmented electroplating gold finger according to claim 1, wherein in the step a, each of the golden fingers is composed of several segmented parts arranged longitudinally, the segmented parts near an outside are connected to an external circuit, and the remaining segmented parts are respectively connected to the side lead through a conductive wire.

3. The method of the segmented electroplating gold finger according to claim 2, wherein one end of the side lead is connected to the gold finger, and another end is connected to a bus.

4. The method of the segmented electroplating gold finger according to claim 1, wherein between the step a and the step b, detection of a size specification of the gold finger is performed, and a length tolerance of the gold finger is controlled to be +/−0.05 mm.

5. The method of the segmented electroplating gold finger according to claim 1, wherein in the step d, a filin tablet is pasted on the substrate, placed under a parallel exposure machine for exposure, and after developing, the filin table is separated to expose a circuit to be etched, and the image transfer is completed.

6. The method of the segmented electroplating gold finger according to claim 1, wherein the lead channel is composed of long side intervals of the two adjacent gold fingers, and a width of the lead channel on an original manuscript is not less than 0.35 mm.
